(19) United States
(12) Patent Application Publication
(10) Pub. No.: US 2002/0020893 A1
(43) Pub. Date: Feb. 21, 2002

(54) MONOLITHIC ASSEMBLY OF SEMICONDUCTOR COMPONENTS INCLUDING A FAST DIODE

(76) Inventor: ANDRE LHORTE, SAINT AVERTIN (FR)

Correspondence Address: DAVID M DRISCOLL, WOLF GREENFIELD AND SACKS, FEDERAL RESERVE PLAZA, 600 ATLANTIC AVENUE, BOSTON, MA, 02210

(21) Appl. No.: 08/659,422

(22) Filed: Jun. 6, 1996

(30) Foreign Application Priority Data
Jun. 22, 1995 (FR) 95/07737

(51) Int. Cl. H01L 29/861; H01L 31/107

(52) U.S. Cl. 257/481; 257/482; 257/544; 257/603

(57) ABSTRACT

A monolithic assembly of a vertical fast diode with at least one additional vertical component, in which the fast diode is formed by an N-type substrate in one surface of which an N⁺-type continuous region is formed and in the other surface of which a P⁺-type discontinuous region is formed. The bottom surface of the assembly is coated with a single metallization. The other vertical component is, for example, a diode.

### BACKGROUND OF THE INVENTION

1. Field of the Invention

The present invention relates to a monolithic assembly of semiconductor components including at least one vertical fast diode and at least one other vertical component having, with the vertical diode, a common terminal corresponding to a uniform metallization to be soldered on a support.

The present invention more particularly relates to the case where the other component is a diode and where it is desired to have diodes of different speeds integrated in a single monolithic component.

2. Discussion of the Related Art

For example, as shown in FIGS. 1 and 2, two diodes D1 and D2 are frequently assembled in series so that the end terminals A and B and the middle terminal C are accessible. These series diodes have distinct functions. In the case, illustrated in FIG. 2 of television scan circuits, diode D1 is a fast modulation diode (i.e., a diode switching rapidly from the ON to the OFF state) and diode D2 has a damping function. The diode D2 should conventionally have a low forward voltage drop, a low voltage surge when turned on and a practically zero reverse current. It is desired to have the two components formed in a monolithic component and the common terminal C to correspond to a bottom surface metallization so that the diodes may be assembled on a heat sink support to avoid heating.

Conventionally, both diodes D1 and D2 are realized in the form of conventional PIN structures and have intrinsic advantages and drawbacks. They have a low reverse leakage current and forward voltage drops varying from 0.8 to 1.5 volts depending on the current density flowing through them. Thus, PIN diodes are well adapted for constructing diodes such as diode D2. To obtain very fast diodes, which correspond to the desired requirements for diode D1, and if necessary to a lesser extent for diode D2, defects in the substrate must be created, for example by diffusion of metal impurities such as gold or platinum or by electronic radiation of heavy particles.

This last characteristic, i.e., the need for creating defects, makes it difficult to render these structures compatible, on a single chip of an integrated circuit, with other components which are not subjected to such processes. More particularly, when gold diffusion is used to increase the diode's speed, it is practically impossible to limit the extension of the gold diffusion because of the high diffusion speed of gold.

Various trade-offs have been tried in the prior art to obtain ideal diodes having distinct speeds. However, when requirements are too strict, separate discrete diodes must be used. Indeed, if gold or platinum diffusion is to be used to form a rapid diode, this diffusion spreads over the whole component and both diodes will finally have the same speed. Also, it is difficult to limit an area subjected to radiation.

### SUMMARY OF THE INVENTION

An object of the present invention is to provide a new monolithic structure assembling a vertical fast diode with other vertical semiconductor elements, for example a damper diode.

Another object of the present invention is to provide such an assembly in which the fast diode and the other semiconductor element have a common electrode which corresponds to the bottom surface of the component and which can be soldered on a support.

To achieve these objects, the present invention monolithically assembles a vertical fast diode with at least one additional vertical component, in which the fast diode is formed by an N-type substrate in one surface of which an N⁺-type continuous region is formed and in the other surface of which a P⁺-type discontinuous region is formed, the bottom surface of the assembly being coated with a single metallization.

According to an embodiment of the present invention, when the P⁺-type discontinuous region of the fast diode is at the bottom surface of the assembly, the fast diode is surrounded with an isolation wall.

According to an embodiment of the present invention, the other vertical component is a junction diode.

According to an embodiment of the present invention, the other vertical component is a diode of the same type as the first diode but with different characteristics. For example, the discontinuous P⁺-type regions of the two diodes have different proportions.

According to an embodiment of the present invention, the monolithic assembly further results from a carrier lifetime reduction process, such as radiation or diffusion of metal impurities.

The foregoing and other objects, features, aspects and advantages of the invention will become apparent from the following detailed description of the present invention when taken in conjunction with the accompanying drawings.

### BRIEF DESCRIPTION OF THE DRAWINGS

FIGS. 1 and 2 represent assemblies that the present invention aims at realizing;

FIG. 3 is a cross-sectional view of a first example, corresponding to FIG. 1, of an assembly according to the present invention of a fast diode with another diode as a single component;

FIG. 4 is a cross-sectional view of a second example, corresponding to FIG. 2, of an assembly according to the present invention of a fast diode with another diode as a single component; and

FIG. 5 is a cross-sectional view of a further example of an assembly according to the present invention of a fast diode with another diode.

### DETAILED DESCRIPTION

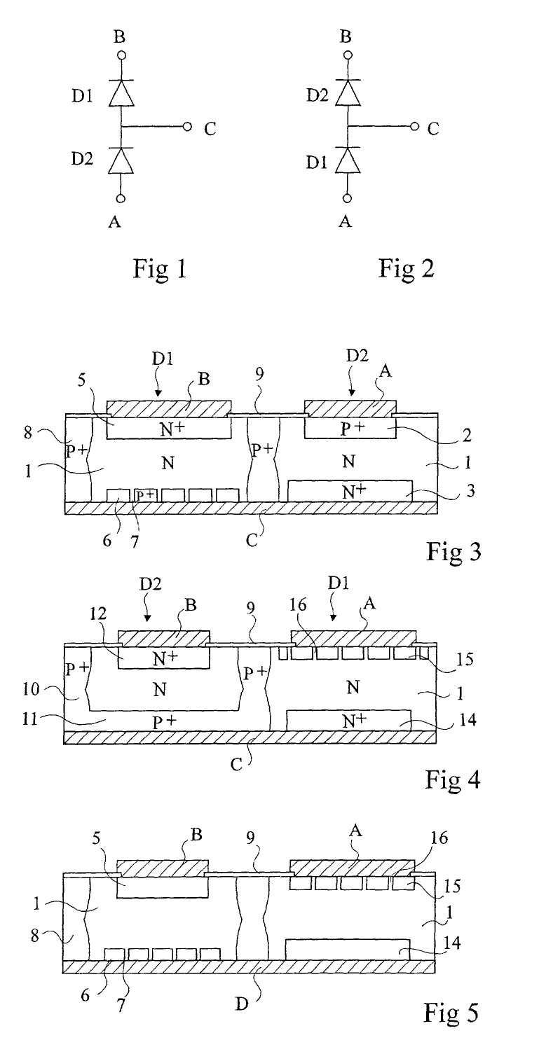

FIG. 3 represents the assembly of two diodes D1 and D2, as in FIG. 1, diode D1 being a fast diode and being connected by its anode to the cathode of diode D2. The assembly is constructed on an N-type substrate 1. Diode D2 is a conventional PIN diode which includes on its upper surface a P-type region 2 and on its lower surface a highly doped N-type region 3. The left portion of FIG. 3 represents a diode combining a Schottky contact with a PN junction. Such diodes were described by B. J. Baliga (IEEE Electron Device Letters, vol. EDL-5, No. 6, June 1984). These diodes have both a low reverse leakage current and a lower forward voltage drop than conventional PIN diodes. This diode includes an N⁺-type cathode region 5 on the upper surface of the substrate and, on the bottom surface of the substrate, a P⁺-type region 6 interrupted by apertures 7. The periphery of this diode, at least along the periphery of the component, is surrounded by a highly doped P-type region 8, formed, for example, by deep diffusion from the lower and upper surfaces of the substrate. The bottom surface of the component is coated with a metallization C which constitutes the anode of diode D1 and the cathode of diode D2. The metallization forms an ohmic contact with region 6 and a Schottky contact with the portions of substrate N appearing in apertures 7. Region 2 is coated with a metallization A and region 5 is coated with a metallization B. The metallizations A, B, C correspond to terminals A, B, C of FIG. 1, respectively. The upper surface of the component, outside the regions where it contacts metallizations A and B, is coated with an insulating layer 9, usually a silicon oxide layer.

An exemplary metallization forming a Schottky contact, comprises aluminum or a silicide of, for example, platinum, nickel, molybdenum or a mixture thereof or of other metals providing the same function. For an upper surface contact, the silicide can be coated with a layer acting as a diffusion barrier such as TiW or TiN and aluminum. For a bottom surface contact, the last layer must withstand soldering and is, for example, of NiAu or NiAg. If the initial layer is a silicide, an intermediate layer acting as a diffusion barrier may be provided.

It should be noted that this structure can be soldered by the lower metallization C on a support. Indeed, even if the soldering overlaps lateral portions of the component, this overlapping does not cause short-circuits because of the P-type isolation wall 8.

FIG. 4 represents a structure implementing the circuit of FIG. 2. In this case, diode D2 is formed in a well surrounded by a P-type isolation wall 10 connecting the junction termination to the upper surface of the chip. The bottom surface of diode D2 is coated with a P-type region 11 and its upper surface includes an N-type region 12 coated with a metallization B. Diode D1 is symmetrical with the diode illustrated in FIG. 3 and includes on the lower surface an N⁺-type region 14 and on the upper surface a P-type region 15 that is interrupted by apertures 16 and coated with a metallization A. The bottom surface of the diode is coated with a uniform metallization C. In this case, because of the presence of the isolation wall 10, the structure can also be soldered on a support without incurring any risk.

FIG. 5 represents a structure assembling two Schottky/bipolar-type diodes. The left portion of FIG. 5 corresponds to the left portion of FIG. 3 and the right portion of FIG. 5 corresponds to the right portion of FIG. 4. Diodes with different characteristics can be obtained by suitably selecting the design and structure of each diode. Indeed, an increase of the area including a Schottky contact (with a constant total area) or a design of the diffused areas minimizing their injection increases the diode's speed.

The above description indicated how the selection of two diodes, wherein at least one is of the Schottky/bipolar-type, provides diodes having different speeds. In addition, the creation of a defect (metal diffusion or radiation) can be achieved for increasing the speed of the two diodes while maintaining a difference in speed between them.

Thus, the fundamental aspect of the present invention lies in the assembly of vertical components, one of which is a Schottky/bipolar diode, where at least one of the vertical structures is surrounded by an isolation wall to allow soldering by the bottom surface of the component. The other vertical component, other than the fast Schottky/bipolar diode, can be any desired vertical component, for example a thyristor.

Having thus described at least one illustrative embodiment of the invention, various alterations, modifications and improvements will readily occur to those skilled in the art. Such alterations, modifications, and improvements are intended to be within the spirit and scope of the invention. Accordingly, the foregoing description is by way of example only and is not intended to be limiting. The invention is limited only as defined in the following claims and the equivalents thereto.

1. A monolithic assembly of a vertical fast diode with at least one additional vertical component, wherein the fast diode is formed by an N-type substrate in one surface of which an N⁺-type continuous region is formed and in another surface of which a P⁺-type discontinuous region is formed, a bottom surface of the assembly being coated with a single metallization.

2. The monolithic assembly of claim 1, wherein, when the P⁺-type discontinuous region of the fast diode is at the bottom surface of the assembly, said fast diode is surrounded with an isolation wall.

3. The monolithic assembly of claim 1, wherein the at least one additional vertical component is a junction diode.

4. The monolithic assembly of claim 1, wherein the at least one additional vertical component is a diode of a same type as the first diode but with different characteristics.

5. The monolithic assembly of claim 4, wherein the discontinuous P⁺-type regions of the two diodes have different proportions.

6. The monolithic assembly of claim 1, wherein the monolithic assembly results from a carrier lifetime reduction process, such as radiation or diffusion of metal impurities.
